(19) United States
(12) Patent Application Publication
(10) Pub. No.: US 2026/0352231 A1
(43) Pub. Date: Nov. 5, 2026

(54) CONCURRENT FORWARD ERROR CORRECTION (FEC) AND CYCLIC REDUNDANCY CHECK (CRC)

(71) Applicant: Rambus Inc., San Jose, CA (US)

(72) Inventor: Yu Cheng Liao, Zhubei City (TW)

(21) Appl. No.: 19/485,663

(22) PCT Filed: May 22, 2024
(86) PCT No.: PCT/US2024/030615

§ 371 Date: Nov. 18, 2025

Related U.S. Application Data
(60) Provisional application No. 63/468,501, filed on May 23, 2023.

(51) Int. Cl. H03M 13/09

(52) U.S. Cl. CPC H03M 13/09

(57) ABSTRACT

A device includes a receiver coupled with a link and including control logic, the control logic to receive data bits corresponding to a first set of data. The control logic may also perform a forward error correction (FEC) operation on the data bits to generate an error location responsive to receiving the data bits. The control logic may also perform a cyclic redundancy check (CRC) operation on the data bits to generate a first CRC value, wherein the CRC operation and FEC operation are performed concurrently. The control logic may determine a second CRC value after performing the FEC operation, the second CRC value based on the error location and generate a third CRC value corresponding to the first set of data responsive to performing the CRC operation and determining the second CRC value.

### TECHNICAL FIELD

Some embodiments pertain to processing resources used to perform and facilitate concurrent forward error correction (FEC) and Cyclic Redundancy Check (CRC).

### BACKGROUND

Communication systems transmit signals from a transmitter to a receiver via a communication channel or medium (e.g., cables, printed circuit boards, links, wirelessly, etc.) For example, a communication system may transmit signals over a peripheral component interconnect express (e.g., a PCIe or PCI-e bus). In such examples, data may be communicated between the transmitter and receiver in a fixed length—e.g., in a flit format, where each flit has a same number of bits. In some examples, to ensure the data is reliably communicated over the interconnect, the receiver may perform one or more error correction operations. For example, the receiver may perform a forward error correction (FEC) operation and a cyclic redundancy check (CRC) operation when receiving the flit. Conventional solutions perform one error operation before the other. For example, the receiver may perform the FEC operation before performing the CRC operation. Accordingly, the receiver may experience additional latencies when receiving the data by having to perform each error operation independently and sequentially.

### BRIEF DESCRIPTION OF DRAWINGS

Various embodiments in accordance with the present disclosure will be described with reference to the drawings, in which:

FIG. 1 is an example communication system, in accordance with some embodiments;

FIG. 2 is an example communication system illustrating concurrent cyclic redundancy check (CRC) and forward error correction (FEC) operations, in accordance with some embodiments;

FIG. 3 is an example communication system illustrating a CRC component, in accordance with some embodiments;

FIG. 4 is an example communication system illustrating a CRC component in accordance with some embodiments;

FIG. 5 is a flow diagram of a method for concurrent CRC and FEC operations, in accordance with some embodiments; and

FIG. 6 illustrates an example computer system for concurrent CRC and FEC operations, in accordance with some embodiments.

### DETAILED DESCRIPTION

Technologies for performing error correction operations (e.g., forward error correction (FEC) and cyclic redundancy check (CRC)) are described in the context of communication systems. Specifically, the error correction operations may be performed in the context of a peripheral component interconnect express system (e.g., PCIe or PCI-e system). The following description sets forth numerous specific details, such as examples of specific systems, components, methods, and so forth, in order to provide a good understanding of several implementations of the present disclosure. It will be apparent to one skilled in the art, however, that some implementations of the present disclosure may be practiced without these specific details. In other instances, well-known components or methods are not described in detail or presented in simple block diagram format to avoid obscuring the present disclosure unnecessarily. Thus, the specific details set forth are merely exemplary. Particular implementations may vary from these exemplary details and still be contemplated to be within the scope of the present disclosure.

As described above, communication systems transmit signals from a transmitter to a receiver via a communication channel or medium (e.g., cables, printed circuit boards, links, wirelessly, etc.) The transmitter and receiver may be examples of personal computer components (e.g., graphics processing unit (GPUs), storage devices (e.g., volatile or non-volatile memory devices), central processing units (CPUs), data processing units (DPUs), graphics cards, etc. In some examples, the transmitter and receiver may be used in data-centric applications in internet of things (IOT), automotives, medical, etc. In some implementations, the transmitter and receiver may communicate according to a communication protocol. For example, a communication system may transmit signals over a peripheral component interconnect express link (e.g., a PCIe or PCI-e bus). In such implementations, each receiver and transmitter may include a PCIe controller that may organize data into packets for transmission and perform error correction operations on received data.

In some embodiments, the communication system may utilize PCIe 6.0 (e.g., the sixth generation of PCIe). In some embodiments, the communication system may utilize pulse amplitude modulation with four levels (e.g., PAM4 signaling) that combines two (2) bits per clock cycle for four amplitude levels (e.g., 00, 01, 10, 11). In some implementations, the communication system may organize data packets in flow control units of fixed lengths—e.g., the data may be communicated according to a FLIT mode, where data is transmitted in flits each having a same fixed length. For example, each flit may include 2048 bits. In some embodiments, the system may take multiple cycles to transmit a single flit. For example, if the system's internal data path is 512 bits, the flit may take four (4) cycles to be transmitted between the receiver and transmitter.

In some embodiments, due to the PAM4 signaling, there may be a high bit error rate (BER). Accordingly, the system may use forward error correction (FEC) to mitigate the higher error rate—e.g., the system may use FEC to ensure the data received at the receiver is the same as the data transmitted by the transmitter. In some embodiments, the FEC may be an addition of a number of bits in the flit to reduce the probability of a bit error during the transmission. However, the FEC alone may not be enough to reduce the link errors. In some embodiments, the system may also perform cyclic redundancy check (CRC) operations—e.g., an error detecting code to detect accidental changes to the digital data during transmission by attaching a short check value within each flit. For example, a flit may include 242 bytes of data payload, eight (8) bytes of CRC values, and 6 bytes of FEC code. In some embodiments, the system may wait until the end of receiving the flit before performing the FEC and CRC operations—e.g., the data inside the flit may be used after the FEC and CRC check pass.

Some solutions may perform the FEC operation first and then perform the CRC operation—e.g., the CRC values may rely on corrected data as a result of the FEC operation. In some implementations, the system may first input data into an FEC component (e.g., FEC engine) that performs the FEC operation. As described above, the flit may be transmitted in four parts, each part transmitted during one (1) clock cycle. Accordingly, the FEC operation may take four (4) cycles to perform. After the FEC operation, the system may input the modified data into a CRC component (e.g., CRC engine) to perform the CRC operations. In some embodiments, the CRC operation may also take four (4) cycles. In such embodiments, the system may experience eight (8) cycles of delay as a result of the FEC and CRC operations—e.g., performing the operations independently and sequentially may cause an increased latency during data transmission.

Advantageously, aspects of the present disclosure may address the deficiencies above and other technical problems by performing the cyclic redundancy check (CRC) operation and forward error correction (FEC) operation concurrently or at a same time. For example, the system may pre-calculate possible CRC values for a data payload included in a flit and utilize the known values to correct errors detected by an FEC operation. In some embodiments, a first CRC component (e.g., CRC decoder) may perform the CRC operation on data received—e.g., before the data undergoes an FEC operation. Concurrently, an FEC component (e.g., FEC decoder) may output an error to a second simplified CRC component to generate correct CRC data. For example, the second CRC component may use a look up table and exclusive OR (XOR) logic to determine a CRC value from a wrong byte (e.g., from an error byte flagged by the FEC engine). That is, the output of the FEC component may be a three (3) error byte location corresponding to errors in the data. Based on a fixed-length CRC algorithm, toggling one bit will contribute to a known fixed change in the CRC value. By pre-calculating all CRC values and knowing the error byte and error parity, a final correct CRC may be calculated.

In some embodiments, the system may use additional XOR logic to logically combine (e.g., XOR) the calculated CRC from the wrong byte and the calculated CRC from the original data (e.g., XOR the outputs of the first and second CRC components). In such embodiments, the CRC correctness may be determined with a reduced latency. For example, the system may perform the CRC operation at the first CRC component concurrently with the FEC operation at the FEC component. In examples where the flit is transmitted over four (4) cycles, the FEC and CRC operation may concurrently happen within four (4) clock cycles. In other embodiments, the flit may be transmitted over a different number of clock cycles (e.g., one, two, three, five, six, etc.). The system may then take an additional clock cycle to compare the CRC values generated by the first CRC component and the second CRC component to calculate the correct CRC values. Accordingly, the process may take a reduced number of clock cycles compared with some solutions.

Utilizing concurrent FEC and CRC operations may reduce latency in the system and improve a time for processing data at a receiver. That is, by performing the error correction operations in a shorter amount of time, the receiver may process received data in a reduced number of clock cycles as compared with some solutions.

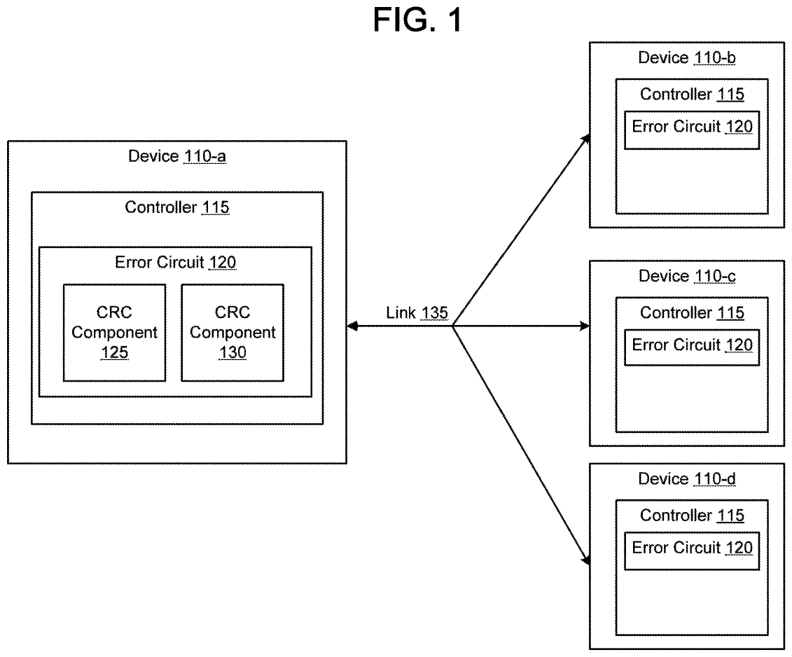

FIG. 1 illustrates an example communication system 100 according to some example embodiments. The system 100 includes devices 110 (e.g., device 110-a, device 110-b, device 110-c, and device 110-d) coupled via a link 135 (e.g., a communication network). In some embodiments, devices 110 are two end-point devices in a computing system, such as a central processing unit (CPU) or graphics processing unit (GPU). In some embodiments, devices 110 are two servers. In one example embodiment, devices 110 correspond to one or more of a Personal Computer (PC), a laptop, a tablet, a smartphone, a server, a collection of servers, or the like. In some embodiments, the devices 110 may correspond to any appropriate type of device that communicates with other devices connected to a common link 135. In some examples, the devices 110 may be used in data-centric applications like in internet of things (IOT), automotives, medical, etc.

According to embodiments, each device 110 may include a transceiver having a transmitter and receiver. In some implementations, the receiver of device 110 may correspond to a GPU, a switch (e.g., a high-speed network switch), a network adapter, a CPU, a memory device, an input/output (I/O) device, other peripheral devices or components on a system-on-chip (SoC), or other devices and components at which a signal is received or measured, etc. As another specific but non-limiting example, the devices 110 nay correspond to servers offering information resources, services, and/or applications to user devices, client devices, or other hosts in the system 100. In one example, devices 110 may correspond to network devices such as switches, network adapters, or data processing units (DPUs).

Examples of the link 135 that may be used to connect the devices 110 include an Internet Protocol (IP) network, an Ethernet network, an InfiniBand (IB) network, a Fibre Channel network, the Internet, a cellular communication network, a wireless communication network, combinations thereof (e.g., Fibre Channel over Ethernet), variants thereof, and/or the like. In one specific but non-limiting example, the link 135 is an example of a peripheral component interconnect express (e.g., a PCIe or PCI-e bus). In some embodiments, the link 135 may communicate via a 6^{th} generation of the PCIe protocol (e.g., PCIe gen 6.0).

The devices 110 includes transceivers for sending and receiving signals, for example, data signals. The data signals may be digital or optical signals modulated with data or other suitable signals for carrying data. The transceiver of devices 110 may include a digital data source, a transmitter, a receiver, and processing circuitry that controls the transceiver. The digital data source may include suitable hardware and/or software for outputting data in a digital format (e.g., in binary code and/or thermometer code). The digital data output by the digital data source may be retrieved from memory (not illustrated) or generated according to input (e.g., user input).

The transmitter of device 110-a includes suitable software and/or hardware for receiving digital data from the digital data source and outputting data signals according to the digital data for transmission over the link 135 to a receiver of devices 110-b through 110-d. Additional details of the structure of the transmitter are discussed in more detail below with reference to the figures.

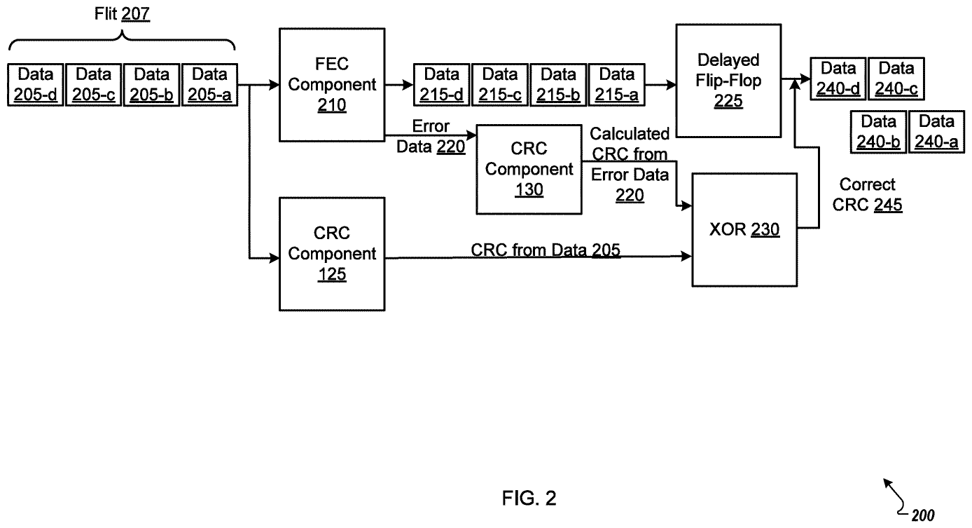

The receiver of devices 110 may include suitable hardware and/or software for receiving signals, such as data signals from the link 135. For example, the receiver of device 110 may include components for receiving processing signals to extract the data for storing in a memory, as described in detail below with respect to FIG. 2-FIG. 5.

The processing circuitry included in device 110 may comprise software, hardware, or a combination thereof. For example, the processing circuitry may include a memory including executable instructions and a processor (e.g., a microprocessor) that executes the instructions on the memory. The memory may correspond to any suitable type of memory device or collection of memory devices configured to store instructions. Non-limiting examples of suitable memory devices that may be used include Flash memory, Random Access Memory (RAM), Read Only Memory (ROM), variants thereof, combinations thereof, or the like. In some embodiments, the memory and processor may be integrated into a common device (e.g., a microprocessor may include integrated memory). Additionally or alternatively, the processing circuitry may comprise hardware, such as an application-specific integrated circuit (ASIC). Other non-limiting examples of the processing circuitry include an Integrated Circuit (IC) chip, a Central Processing Unit (CPU), a General Processing Unit (GPU), a microprocessor, a Field Programmable Gate Array (FPGA), a collection of logic gates or transistors, resistors, capacitors, inductors, diodes, or the like. Some or all of the processing circuitry may be provided on a Printed Circuit Board (PCB) or collection of PCBs. It should be appreciated that any appropriate type of electrical component or collection of electrical components may be suitable for inclusion in the processing circuitry. The processing circuitry may send and/or receive signals to and/or from other elements of the transceiver to control the overall operation of the transceiver of device 110.

The transceiver or selected elements of the transceiver may take the form of a pluggable card or controller for the device 110. For example, the transceiver or selected elements of the transceiver may be implemented on a network interface card (NIC).

Although not explicitly shown, it should be appreciated that devices 110 may include other processing devices, storage devices, and/or communication interfaces generally associated with computing tasks, such as sending and receiving data.

In some implementations, a transceiver of devices 110 may include a controller 115. In some embodiments, the controller 115 is associated with the PCIe protocol—e.g., the controller 115 may transmit and receive data according to the PCIe protocol. In some embodiments, each device 110 of the system 100 includes the controller 115. In some embodiments, the controller 115 may include an error circuit 120 for processing received data from another device 110. For example, device 110-b may include an error circuit 120 to process received data from device 110-a. In some embodiments, the error circuit 120 may include a CRC component 125 and a CRC component 130. In some embodiments, the CRC component 125 is to perform a cyclic redundancy check (CRC) operation to calculate a CRC value associated with data received at the receiver. In some implementations, CRC component 125 is to perform the CRC operation concurrent with a forward error correction operation (FEC) performed at an FEC component as described with reference to FIG. 2. In some embodiments, the CRC component 130 is to generate a second CRC value that may be used to modify or otherwise correct the CRC value generated by CRC component 125 as described with reference to FIG. 2. For example, the CRC component 130 may receive error data from the FEC component—e.g., receive an error byte location. In some embodiments, the CRC component 130 may include a look up table storing CRC values associated with each error byte location. Accordingly, the CRC component 130 may output a respective second CRC value associated with the error byte location. In some embodiments, the error circuit 120 may include exclusive OR (XOR) logic and XOR the CRC value generated by the CRC component 125 and second CRC value generated by component 130 to determine a correct CRC associated with data as described with reference to FIG. 2.

FIG. 2 illustrates an example error circuit 200 within a communication system 100 as described with reference to FIG. 1, according to some example embodiments. The system 200 includes a cyclic redundancy check (CRC) component 125 and CRC component 130 as described with reference to FIG. 1. In some embodiments, the system 200 may also include a forward error correction (FEC) component 210, a delayed flip-flop (DFF) 225, and exclusive OR (XOR) logic 230.

In some embodiments, the system 200 may be located within a controller 115 as described with reference to FIG. 1—e.g., within a PCIe controller or PCIe 6.0 controller. In some implementations, the system 200 may be utilized when a respective device 110 (e.g., device 110-b through device 110-d as described with reference to FIG. 1) receives data from a transmitter—e.g., from device 110-a. In some embodiments, the system 200 may receive data 205-a, data 205-b, data 205-c, and data 205-d. Collectively, the data 205 may be referred to as a flit 207—e.g., a fixed length of data may be transmitted by a transmitter to the receiver by organizing packets into flits. In this example, the flit 207 takes four (4) clock cycles to receive. In other embodiments, the flit 207 may take more than or less than four (4) clock cycles to receive—e.g., the flit 207 may take one, two, three, five, six, etc., clock cycles to receive. In some embodiments, a number of clock cycles to receive the flit 207 may depend on an internal data path or size of the link 135 as described with reference to FIG. 1—e.g., the larger the internal data path, the smaller number of clock cycles it may take to receive the flit 207. In some embodiments, the flit 207 may be 2048 bits, where each data 205 consists of 512 bits. In such embodiments, the flit 207 may include 242 bytes of data payload, 8 bytes corresponding to CRC values, and 6 bytes corresponding to an FEC code. In other embodiments, the flit 207 may include a different number of bytes—e.g., there may be additional or reduced bytes for the data payload, CRC values, and FEC code. It should be noted, even though the flit 207 may include additional or reduced bytes, each flit 207 may stay at a fixed length.

In some implementations, FEC component 210 is to receive flit 207—e.g., data 205-a through data 205-d across four (4) clock cycles. In some embodiments, the FEC component 210 may perform an FEC operation. In some embodiments, the system may utilize block codes for the FEC operation—e.g., in a block code a message or data to be transmitted is divided into fixed lengths of bits (e.g., into flits 207) and redundant bits are added for the error correction. In some embodiments, the FEC component 210 may perform the FEC operation by using hamming codes (e.g., block code capable of detecting two simultaneous error bits and correcting single bit errors), Reed-Solomon code (e.g., block codes that may correct burst errors in the received data flit 207), and low-density parity check code (e.g., block code specified by a parity-check matrix containing a low density of ones (1's). In some implementations, the FEC component 210 may be capable of utilizing convolutional codes—e.g., the FEC component 210 may utilize a binary convolution code where an encoder processes an input sequence of bits to generate a sequence of output bits, the sequence of bits having an arbitrary length. In some embodiments, the FEC component 210 may determine and correct errors for the flit 207. For example, the FEC component 210 may generate corrected data (e.g., data that undergoes an FEC operation) 215-a through 215-d.

In some embodiments, the data 215-a through data 215-d may still contain errors—e.g., a CRC value of the data 215-a through 215-d may be incorrect since the CRC operation has not yet been performed on data 215-a through data 215-b. In some embodiments, the FEC component 210 may also generate error data 220. In some embodiments, the FEC component 210 may determine an error bit or error byte location. In such embodiments, the error data 220 may include the error byte location and corresponding error data. For example, the FEC component 210 may output a three (3) error byte location—e.g., output a first error byte location, a second error byte location, and a third error byte location. In some implementations, a number of error byte locations outputted by the FEC component 210 may depend on a number of groups the data 205-a through 205-d is spilt into. For example, in some embodiments, the data payload of flit 207 may be split into three (3) groups, each group having 81 or 82 bytes. Accordingly, the first error byte location may correspond to a first group, the second error byte location may correspond to a second group, and the third error byte location may correspond to a third group. In some embodiments, the data payload may be split into more than or less than three (3) groups. In such embodiments, the FEC component 210 may output more than or less than three (3) error byte location, each error byte location corresponding to a different group.

In some embodiments, CRC component 130 is to perform a CRC operation on the error data 220 received from the FEC 210—e.g., the CRC component 130 may determine the CRC value derived from a wrong byte or error byte location of the flit 207. In some embodiments, the CRC operation is type of checksum that produces a fixed-length data set based on received data. In some embodiments, the CRC component 130 may perform the CRC operation by evaluating a check value (e.g., the CRC bytes included in the flit 207) by finding a remainder of a polynomial division of the data transmitted. In other embodiments, the CRC component 130 may map the error data 220 to a fixed length—e.g., a hash function. In some implementations, because the CRC algorithm is fixed in length, each error (e.g., bit toggle) contributes a known fixed change in the CRC value generated. In that, if the system 200 determines the error byte location (e.g., the error byte and error parity), the system 200 may determine the impact the error has to a final CRC value.

For example, consider an illustrative case (e.g., a case that is for illustration purposes only and is not limiting on the claims) where there is a three (3) bit input each having a value of ‘0’ or ‘1’—e.g., an input (A, B, C) where A, B, and C may be either a ‘0’ or a ‘1.’ In some embodiments, based on a known CRC algorithm (e.g., based on a CRC algorithm used by CRC component 130 and CRC component 125), a CRC of an input (0,0,0) is 0. In that, a correct CRC of (A, B, C) is equal to CRC (A,0,0) \hat{ }CRC (0,B,0) \hat{ }CRC (0,0,C). If there is an error with the bit B, then a wrong CRC value would be calculated. In some embodiments, the bit B could originally have a value ‘0’ and be toggled (e.g., during transmission the bit value may change) to a value ‘1.’ In such embodiments, CRC (0, B,0) would not be equal to zero—e.g., because a CRC (0,0,0) is 0, having the bit B change from ‘0’ to ‘1’ would change the CRC value. Accordingly, a wrong CRC is generated. In one example, the CRC value may be corrected by utilizing exclusive OR (XOR) logic and doing a XOR by CRC (0, ~B, 0) e.g., the correct CRC value may be obtained by doing an XOR operation with (0,~B, 0). In this example, (0, ~B, 0) would be (0,1,0). In a second embodiment, the bit B could originally have a value ‘1’ and be toggled to a value ‘0.’ In such an embodiment, CRC of (0, ~B,0) would be 0—e.g., the bit value changing to ‘1’ would cause a wrong CRC value of 0 to be calculated based on a CRC of an input (0,0,0) being 0. In the second embodiment, the correct CRC may be determined by performing an XOR by CRC (0, B,0) which is CRC (0,1,0)—e.g., an XOR of (0, ~B,0) and (0, B,0) results in corrected CRC value. Accordingly, in either embodiment (e.g., whether the bit “B” flips from ‘0’ to ‘1’ or from ‘1’ to ‘0’), a correct CRC may be determined by doing the same XOR CRC (0,1,0).

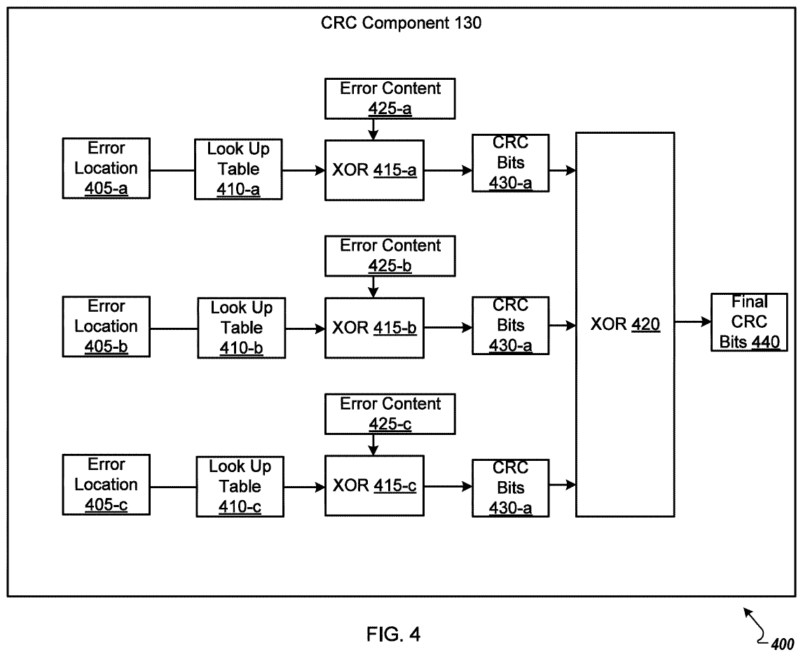

The above examples illustrate that as long as a wrong byte and wrong bit location are known, the correct CRC may be generated—e.g., the FEC component 210 may output the error byte location, the CRC component 130 may look up a pre-calculated CRC value based on the error location, and the XOR logic 230 may receive the pre-calculated CRC value, the CRC value calculated by CRC component 125, and perform an XOR operation to correct the CRC as mentioned above. In some embodiments, the CRC calculations may be complex and difficult or it may be impossible to perform the CRC for 242 bytes in one cycle. Accordingly, the CRC component 130 may include pre-determined look-up tables as described with reference to FIG. 4. Additional details regarding an internal process of the CRC component 130 is described with reference to FIG. 4.

In some embodiments, CRC component 125 is configured to calculate a CRC value from flit 207. As described above, because the CRC component 125 receives the data directly (e.g., before an FEC operation is performed), there may be errors in the flit 207 received at the CRC component 125. In that, the CRC component 125 may determine a CRC value for “wrong data” or data otherwise includes errors. In some implementations, the CRC component 125 performs a CRC operation that is a type of checksum that produces a fixed-length data set based on received data. In some embodiments, the CRC component 125 may perform the CRC operation by evaluating a check value (e.g., the CRC bytes included in the flit 207) by finding a remainder of a polynomial division of the data transmitted. In other embodiments, the CRC component 125 may map the flit 207 to a fixed length—e.g., a hash function.

In some embodiments, XOR logic 230 is to receive the calculated CRC from error data 220 and a CRC value from CRC component 125—e.g., receive a CRC value derived from the flit 207. In some embodiments, the calculated CRC from error data 220 and the CRC value from CRC component 125 may be the same. In such embodiments, there may be no error related to the CRC values—e.g., there may be no errors as a result of transmitting the data to the system 200. In other embodiments, the XOR logic 230 may receive a different CRC value from CRC component 125 as compared to a CRC value received from CRC component 130. In some embodiments, the XOR logic 230 may output a correct CRC 245 based on receiving the different CRC values from the CRC component 125 and CRC component 130, respectively. For example, as illustrated above, if the FEC component 210 outputs a second error byte location (e.g., indicating an error in bit “B”), the CRC component 130 may output a value CRC (0,1,0) and XOR the CRC from data 205 by CRC (0,1,0) to get a correct CRC 245. In other implementations, the CRC components 125 and 130 may utilize more complicated algorithms. However, as long as the error byte location is known, the CRC component 130 may generate a CRC value that corrects potential errors in the CRC from data 205.

In some embodiments, delayed flip-flop (DFF) 225 may receive data 215 (e.g., data 205 corrected by the FEC component 210). In some embodiments, the DFF 225 may delay transmitting the data by one (1) or more cycles. For example, in embodiments where an error is calculated, it may take one (1) clock cycle to determine the correct CRC after the FEC component 210 and CRC component 125 output a value—e.g., the FEC component 210 and CRC component 125 may perform their respective error correction operations concurrently. For example, the FEC component 210 and CRC component 125 may each take four (4) clock cycles. In other embodiments, the FEC component 210 and CRC components 125 may take more than or less than four (4) clock cycles depending on a number of data 205 portions in a flit 207—e.g., if the flit 207 is split into two (2) data 205 portions, the FEC component 210 and CRC component 125 may take two (2) clock cycles to perform the error operation. In some implementations, the DFF 225 is optional—e.g., the DFF 225 may optionally delay the data 215 if waiting for a correct CRC 245 to be generated.

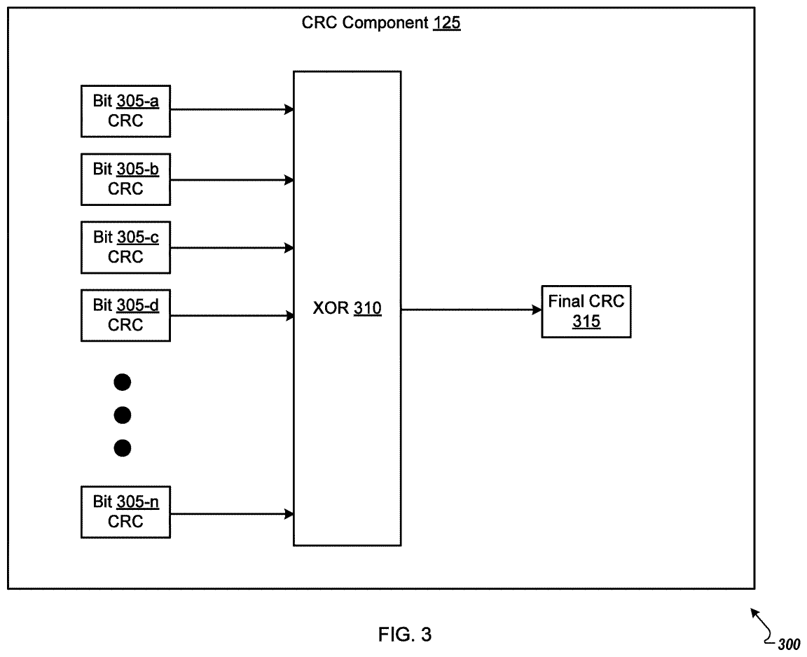

FIG. 3 illustrates an example communication system 300 according to some example embodiments. The system 300 includes a CRC component 125 as described with reference to FIGS. 1 and 2. In some embodiments, CRC component 125 may include an exclusive OR (XOR) logic 310.

In some embodiments, the CRC component 125 may receive a CRC value associated with each bit 305 of a flit 207. For example, the CRC component 125 may receive a first CRC value for a first bit, a second CRC value for a second bit, an n^{th} CRC value for an n^{th} bit—e.g., receive a bit 305-a CRC value for the first bit 305-a, receive a bit 305-b CRC value for the second bit 305-b, and receive a bit 305-n CRC value for the n^{th} bit 305-n. In some embodiments, each CRC value associated with a bit may be a predetermined number of bits according to a CRC algorithm used by the CRC component 125. For example, each CRC value associated with a bit 305 may be 64 bits. In some embodiments, a number of CRC values associated with bits 305 may be based on a number of bits in a flit 207 as described with reference to FIG. 2—e.g., may be based on a number of data bits associated with a data payload in flit 207. For example, in some implementations, flit 207 may include 242 bytes of data payload—e.g., the flit 207 may include 1936 bits associated with the data payload. In such an embodiment, the XOR logic 310 may receive 1936×64 bits.

In some embodiments, the XOR logic 310 may be configured to XOR the CRC values received to generate a final CRC value 315. In embodiments where each CRC value associated with bits 305 is 64 bits, the CRC component 125 may utilize a CRC-64—e.g., a cyclic redundancy check 64-bit algorithm. In some embodiments, the XOR logic 310 may generate a CRC value having a number of bits equal to a number of bits for a CRC value associated with a respective bit 305—e.g., if each CRC value is 64 bits, the XOR logic 310 may XOR each of the received CRC values associated with each bit 305 into a final CRC value 315 comprising 64 bits.

FIG. 4 illustrates an example communication system 400 according to one example embodiment. The system 400 includes CRC component 130 as described with reference to FIGS. 1 and 2. In some embodiments, the CRC component 130 includes look up tables 410 (e.g., look up table 410-a, look up table 410-b, and look up table 410-c), XOR logic 415, and XOR logic 420.

In some embodiments, the CRC component 130 is to generate a CRC value based on receiving error data (e.g., error data 220 as described with reference to FIG. 2). For example, as described with reference to FIG. 2, the CRC component 130 may receive an error location from FEC component 210. In some embodiments, the error location may be three (3) bytes, each byte representing an error location for a part of the flit 207 as described with reference to FIG. 2. For example, the error location 405-a may be associated with a first group of bytes of flit 207, error location 405-b may be associated with a second group of bytes of flit 207 and error location 405-c may be associated with a third group of bytes of flit 207—e.g., in embodiment with 242 bytes of data payload, the error location 405-a may be associated with a first 82 bytes of the flit 207, the error location 405-b may be associated with a next 81 bytes of the flit 207, and the error location 405-c may be associated with a final 81 bytes of the flit 207. As described with reference to FIG. 2, the CRC component 130 may receive any number of error byte locations 405 based on a number of groups the flit 207 is split into for the CRC component 130—e.g., the CRC component 130 could receive four error byte locations if the flit 207 is processed in four groups at the CRC component 130.

In some implementations, look up tables 410 may receive a respective error location 405 and generate a CRC value based on the received error location 405. For example, referring to the illustrative example described with reference to FIG. 2 (e.g., utilizing an input (A, B, C) where A, B, and C may be either a ‘0’ or a ‘1.’), in an embodiment, error location 405-b may indicate a location of the error is associated with a value “B.” As described with reference to FIG. 2, whether the value “B” flips from a ‘0’ to a ‘1’ or from a ‘1’ to a ‘0,’ the error may be corrected by performing an XOR operation with a CRC value (0,1,0). That is, based on the location of the error being at the value “B,” a known CRC value (0,1,0) may be generated to correct the error—e.g., when the CRC component 130 uses a CRC algorithm with a fixed length, knowing the location of the error is enough to correct the CRC even if it is not known whether the value “B” flipped from a ‘0’ to a ‘1’ or the value “B” flipped from a ‘1 to a ‘0’. In an embodiment, the look up table may store a CRC value for each respective error location 405. For example, the look up table 410-b may store a CRC value (0,1,0). When the look up table 410-b receives the error location (e.g., that the error is with the value “B”), the CRC component 130 may use the look up table 410 to determine the corresponding CRC value (e.g., the CRC value (0,1,0). As described with reference to FIG. 2, the CRC component 130 may utilize a CRC-64—e.g., a cyclic redundancy check 64-bit algorithm. Accordingly, the stored CRC values in the lookup table may each consist of 64 bits. That is, as each error byte location 405 consists of eight (8) bits, the look up table 410 may output 64×8 bits—e.g., a 64-bit CRC value for each of the bits of the error byte location.

In some embodiments, XOR logic 415 is to receive a stored CRC value from look up table 410 and an error content 425—e.g., XOR logic 415-b may receive a CRC value associated with error location 405-b from the look up table 410-b. In some embodiments, the XOR logic 415 is to perform an XOR operation with respect to the stored CRC value and the error content 425. As described with reference to the look up tables 410, the XOR logic 415 may receive a CRC value for each byte of the error byte location 405—e.g., receive a 64 bit CRC value for each bit of the error byte location 405. In some embodiments, the look up table 410 may generate CRC values that are not associated with an error—e.g., the look up table 410 generates a CRC value for each bit of the error byte location. In some embodiments, some of the bits of the error byte location indicate there is no error at a respective location—e.g., a generated value of ‘1’ may impact a CRC value determined while a generated value of ‘0’ may have no impact on the CRC. For example, if the look up table 410 generated the CRC value (0,1,0), it would indicate an error at “B” but there would be no impact to the CRC value of “A” or “C.” In some embodiments, the error byte content 425 may accordingly indicate a content of the error—e.g., indicate the error determined by the FEC component 210. In some implementations, the XOR logic 415 may XOR the CRC value generated by the look up table 410 by the error content 425 to generate a CRC value associated with the error location and error content—e.g., CRC bits 430 may each consist of 64 bits corresponding to the respective error location 405 and error content 425.

In some embodiments, XOR logic 420 is to receive CRC bits 430 associated with each respective error location 405 and error content 425. In some embodiments, the XOR logic 420 is to XOR the received CRC bits 430 to generate final CRC bits 440. In some embodiments, the final CRC bits 440 corresponds to the calculated CRC from error data 220 as described with reference to FIG. 2. In such embodiments, the CRC component 130 may output the final CRC bits 440 to XOR logic 230 as described with reference to FIG. 2. Accordingly, the XOR logic 230 may utilize the final CRC bits 440 to correct any errors with a CRC generated by CRC component 125 as described with reference to FIG. 2. By utilizing the CRC component 130, the system 200 as described with reference to FIG. 2 may concurrently perform the FEC and a CRC operation at the CRC component 125. In such embodiments, the system 200 may then correct the CRC value generated from the CRC component 125 with the final CRC bits 440 determined by CRC component 130. In that, the system 200 may correct the CRC value by determining the error location and error byte content at the FEC component 210.

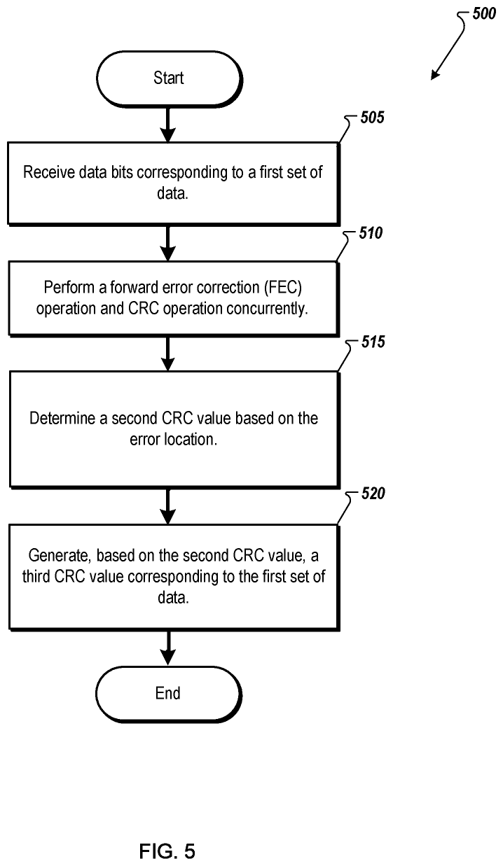

FIG. 5 illustrates an example flow diagram of a method 500 for concurrently performing a forward error correction (FEC) operation and cyclic redundancy check (CRC) operation, according to some implementations. The method 500 may be performed by processing logic comprising hardware, software, firmware, or any combination thereof. In some embodiments, the method 500 is performed by the system 100 and 200 as described with reference to FIGS. 1 and 2—e.g., the method 500 may be performed at the controller 115 by the FEC component 210, CRC component 125, CRC component 130, XOR logic 230, and delayed flip-flop (DFF) 225. Although shown in a particular sequence or order, unless otherwise specified, the order of the processes may be modified. Thus, the illustrated embodiments should be understood only as examples, and the illustrated processes may be performed in a different order, and some processes may be performed in parallel. Additionally, one or more processes may be omitted in various embodiments. Thus, not all processes are required in every embodiment.

At operation 505, a receiver (e.g., a receiver of device 110 as described with reference to FIG. 1) and/or processing logic may receive data bits corresponding to a first set of data—e.g., receive data 205-a through data 205-d as corresponding to flit 207 as described with reference to FIG. 2. In some embodiments, the receiver is also to receive second data bits corresponding to a second set of data, where the first set of data and the second set of data have a same length—e.g., each flit 207 received may be a same size. In some embodiments, the receiver may receive the data via a link (e.g., link 135 as described with reference to FIG. 1). In some embodiments, the link is an example of a peripheral component interconnect express (PCIe) e.g., the link may communicate according to a 6^{th} generation of PCIe (PCIe gen 6.0). In some implementations, the data bits may also include CRC values and FEC code—e.g., each flit 207 may include a data payload and additional bits that correspond to CRC values and FEC code to ensure reliable transmission of the data payload.

At operation 510, processing logic (e.g., the FEC component 210 as described with reference to FIG. 2) may perform a forward error correction (FEC) operation on the data bits to generate an error location responsive to receiving the data bits. As described with reference to FIG. 2, the processing logic may determine an error location and an error parity associated with the received data. In some embodiments, the processing logic may correct or modify the received data to correct for detected errors. In some embodiments, the processing logic may output error data (e.g., error byte location 405 or error content 425 as described with reference to FIG. 4) to a CRC component—e.g., a simplified CRC component 130 as described with reference to FIG. 4. In some embodiments, the processing logic may output the modified or corrected received bits to a delay flip-flop (e.g., DFF 225 as described with reference to FIG. 2). In some embodiments, the processing logic may determine one or more errors and the DF 225 may delay the received data by one or more clock cycles. In some embodiments, the processing logic may determine an absence of errors responsive to performing the FEC operation—e.g., there may be no errors associated with transmitting the data over the link. In such embodiments, the processing logic may refrain from generating a second CRC value responsive to determining the absence of errors—e.g., the processing logic may refrain from generating the second CRC value described with reference to operation 520.

At operation 510, processing logic (e.g., CRC component 125 as described with reference to FIG. 2) may also perform a cyclic redundancy check (CRC) operation on the data bits to generate a first CRC value, where the CRC operation and the FEC operation are performed concurrently. As described with reference to FIG. 2, the system may perform both the CRC operation and FEC operation concurrently. In some embodiments, the CRC component 125 may generate an incorrect (e.g., wrong) CRC value because the data received has not been corrected by the FEC operation (e.g., because the FEC operation is done concurrently, the CRC component 125 may perform the CRC operation on wrong data or data having errors due to the transmission process).

At operation 515, processing logic (e.g., CRC component 130 as described with reference to FIG. 1) may determine a second CRC value after performing the FEC operation, where the second CRC value is based on the error location. As described with reference to FIG. 2, the processing logic may correct CRC errors via the CRC component 130 if the error location and error parity are known—e.g., the CRC component 130 may utilize a fixed-length CRC algorithm in which a bit flipping values contributes a fixed change to the CRC value. In some implementations, the processing logic may receive the error location—e.g., receive error location 405 as described with reference to FIG. 4. In some embodiments, the processing logic may determine a corresponding CRC value for the error location—e.g., the CRC component 130 may include look up tables that store a plurality of CRC values, where the plurality of CRC values comprises the second CRC value. Accordingly, the processing logic may compare the error location with the table storing the plurality of CRC values and determine the second CRC value corresponds to the error location received. In some embodiments, the CRC component 130 may include multiple look up tables, each look up table storing a plurality of CRC values associated with a portion of the data bits—e.g., the CRC component 130 may include multiple look up tables, each look up table associated with a different portion of data bits as described with reference to FIG. 2.

At operation 520, processing logic may generate a third CRC value corresponding to the first set of data responsive to performing the CRC operation and determining the second CRC value—e.g., XOR logic 230 as described with reference to FIG. 2, may XOR the first CRC value by the second CRC value to generate a third CRC value. In some embodiments, the third CRC is a correct value—e.g., it is the CRC value associated with the received data bits. In some embodiments, the processing logic may utilize the third CRC value to fix any errors present in the data bits—e.g., in data 215-a through data 215-d as described with reference to FIG. 2. Accordingly, the processing logic may concurrently perform the CRC and FEC operation and correct the CRC knowing the error location to help reduce the overall latency of the system.

In some embodiments, the receiver may include a first cyclic redundancy check (CRC) component to perform a first CRC operation and generate a first CRC value on data bits received—e.g., include CRC component 125 as described with reference to FIG. 2. In some embodiments, the receiver may also include a forward error correction (FEC) component to perform an FEC operation and determine an error location associated with the data bits received, where the first CRC operation and the FEC operation are performed concurrently—e.g., include the FEC component 210 as described with reference to FIG. 2. In some implementations, the receiver may also include a second CRC component coupled to the FEC component and to perform a second CRC operation and generate a second CRC value based on the error location determined—e.g., include CRC component 130 as described with reference to FIG. 2. In some embodiments, the receiver may also include an exclusive OR (XOR) logic to logically combine the first CRC value and the second CRC value and generate a third CRC value associated with the data bits received—e.g., XOR logic 230 as described with reference to FIG. 2. In some embodiments, the second CRC component includes a table storing a plurality of CRC values, and where the plurality of CRC values comprises the second CRC value. In some embodiments, the second CRC component may receive the error location, compare the error location with the table storing the plurality of CRC values responsive to receiving the error location, and determine the second CRC value corresponds to the error location received responsive to comparing the error location with the table as described with reference to FIGS. 2 and 4. In some implementations, the FEC component may determine an absence of errors responsive to performing the FEC operation—e.g., the data may be transmitted over the link 135 without errors. In such implementations, the second CRC component may refrain from generating the second CRC value responsive to the FEC component determining an absence of errors—e.g., as there are no errors, the CRC generated by the first CRC component 125 may be correct and additional modification is not needed.

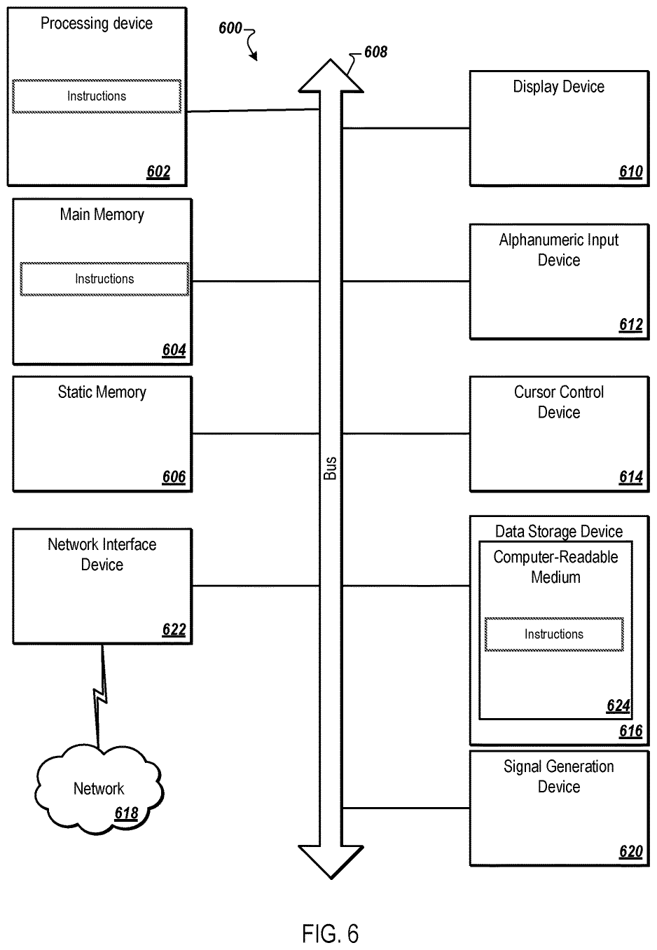

FIG. 6 is a block diagram illustrating an exemplary computer system 600, in accordance with some implementations of the disclosure The computer system 600 executes one or more sets of instructions that cause the machine to perform any one or more of the methodologies discussed herein. Set of instructions, instructions, and the like may refer to instructions that, when executed by computer system 600, cause computer system 600 to perform one or more operations of root device 106 and/or target device 120. The machine may operate in the capacity of a server or a client device in a client-server network environment, or as a peer machine in a peer-to-peer (or distributed) network environment. The machine may be a personal computer (PC), a tablet PC, a set-top box (STB), a personal digital assistant (PDA), a mobile telephone, a web appliance, a server, a network router, switch or bridge, or any machine capable of executing a set of instructions (sequential or otherwise) that specify actions to be taken by that machine. Further, while only a single machine is illustrated, the term “machine” shall also be taken to include any collection of machines that individually or jointly execute the sets of instructions to perform any one or more of the methodologies discussed herein.

The computer system 600 includes a processing device 602, a main memory 604 (e.g., read-only memory (ROM), flash memory, dynamic random access memory (DRAM) such as synchronous DRAM (SDRAM) or Rambus DRAM (RDRAM), etc.), a static memory 606 (e.g., flash memory, static random access memory (SRAM), etc.), and a data storage device 616, which communicate with each other via a bus 608.

The processing device 602 represents one or more general-purpose processing devices such as a microprocessor, central processing unit, or the like. More particularly, the processing device 602 may be a complex instruction set computing (CISC) microprocessor, reduced instruction set computing (RISC) microprocessor, very long instruction word (VLIW) microprocessor, or a processing device implementing other instruction sets or processing devices implementing a combination of instruction sets. The processing device 602 may also be one or more special-purpose processing devices such as an application specific integrated circuit (ASIC), a field programmable gate array (FPGA), a digital signal processor (DSP), network processor, or the like. The processing device 602 is configured to execute instructions of the computer system 100 for performing the operations discussed herein.

The computer system 600 may further include a network interface device 622 that provides communication with other machines over a network 618, such as a local area network (LAN), an intranet, an extranet, or the Internet. The computer system 600 also may include a display device 610 (e.g., a liquid crystal display (LCD) or a cathode ray tube (CRT)), an alphanumeric input device 612 (e.g., a keyboard), a cursor control device 614 (e.g., a mouse), and a signal generation device 620 (e.g., a speaker).

The data storage device 616 may include a non-transitory computer-readable storage medium 624 on which is stored the sets of instructions of the computer system 100 embodying any one or more of the methodologies or functions described herein. The sets of instructions may also reside, completely or at least partially, within the main memory 604 and/or within the processing device 602 during execution thereof by the computer system 600, the main memory 604 and the processing device 602 also constituting computer-readable storage media. The sets of instructions may further be transmitted or received over the network 618 via the network interface device 622.

While the example of the computer-readable storage medium 624 is shown as a single medium, the term “computer-readable storage medium” may include a single medium or multiple media (e.g., a centralized or distributed database, and/or associated caches and servers) that store the sets of instructions. The term “computer-readable storage medium” may include any medium that is capable of storing, encoding or carrying a set of instructions for execution by the machine and that cause the machine to perform any one or more of the methodologies of the disclosure. The term “computer-readable storage medium” may include, but not be limited to, solid-state memories, optical media, and magnetic media.

In the foregoing description, numerous details are set forth. It will be apparent, however, to one of ordinary skill in the art having the benefit of this disclosure, that the disclosure may be practiced without these specific details. In some instances, well-known structures and devices are shown in block diagram form, rather than in detail, in order to avoid obscuring the disclosure.

Some portions of the detailed description have been presented in terms of algorithms and symbolic representations of operations on data bits within a computer memory. These algorithmic descriptions and representations are the means used by those skilled in the data processing arts to most effectively convey the substance of their work to others skilled in the art. An algorithm is here, and generally, conceived to be a self-consistent sequence of operations leading to a desired result. The operations are those requiring physical manipulations of physical quantities. Usually, though not necessarily, these quantities take the form of electrical or magnetic signals capable of being stored, transferred, combined, compared, and otherwise manipulated. It has proven convenient at times, principally for reasons of common usage, to refer to these signals as bits, values, elements, symbols, characters, terms, numbers, or the like.

It may be borne in mind, however, that all of these and similar terms are to be associated with the appropriate physical quantities and are merely convenient labels applied to these quantities. Unless specifically stated otherwise, it is appreciated that throughout the description, discussions utilizing terms such as “authenticating”, “providing”, “receiving”, “identifying”, “determining”, “sending”, “enabling” or the like, refer to the actions and processes of a computer system, or similar electronic computing device, that manipulates and transforms data represented as physical (e.g., electronic) quantities within the computer system memories or registers into other data similarly represented as physical quantities within the computer system memories or registers or other such information storage, transmission or display devices.

The disclosure also relates to an apparatus for performing the operations herein. This apparatus may be specially constructed for the required purposes, or it may include a general purpose computer selectively activated or reconfigured by a computer program stored in the computer. Such a computer program may be stored in a computer readable storage medium, such as, but not limited to, any type of disk including a floppy disk, an optical disk, a compact disc read-only memory (CD-ROM), a magnetic-optical disk, a read-only memory (ROM), a random access memory (RAM), an erasable programmable read-only memory (EPROM), an electrically erasable programmable read-only memory (EEPROM), a magnetic or optical card, or any type of media suitable for storing electronic instructions.

The words “example” or “exemplary” are used herein to mean serving as an example, instance, or illustration. Any aspect or design described herein as “example’ or “exemplary” is not necessarily to be construed as preferred or advantageous over other aspects or designs. Rather, use of the words “example” or “exemplary” is intended to present concepts in a concrete fashion. As used in this application, the term “or” is intended to mean an inclusive “or” rather than an exclusive “or.” That is, unless specified otherwise, or clear from context, “X includes A or B” is intended to mean any of the natural inclusive permutations. That is, if X includes A; X includes B; or X includes both A and B, then “X includes A or B” is satisfied under any of the foregoing instances. In addition, the articles “a” and “an” as used in this application and the appended claims may generally be construed to mean “one or more” unless specified otherwise or clear from context to be directed to a singular form. Moreover, use of the term “an implementation” or “one implementation” or “an implementation” or “one implementation” throughout is not intended to mean the same implementation or implementation unless described as such. The terms “first,” “second,” “third,” “fourth,” etc. as used herein are meant as labels to distinguish among different elements and may not necessarily have an ordinal meaning according to their numerical designation.

For simplicity of explanation, methods herein are depicted and described as a series of acts or operations. However, acts in accordance with this disclosure may occur in various orders and/or concurrently, and with other acts not presented and described herein. Furthermore, not all illustrated acts may be required to implement the methods in accordance with the disclosed subject matter. In addition, those skilled in the art will understand and appreciate that the methods could alternatively be represented as a series of interrelated states via a state diagram or events. Additionally, it should be appreciated that the methods disclosed in this specification are capable of being stored on an article of manufacture to facilitate transporting and transferring such methods to computing devices. The term article of manufacture, as used herein, is intended to encompass a computer program accessible from any computer-readable device or storage media.

In additional implementations, one or more processing devices for performing the operations of the above described implementations are disclosed. Additionally, in implementations of the disclosure, a non-transitory computer-readable storage medium stores instructions for performing the operations of the described implementations. Also in other implementations, systems for performing the operations of the described implementations are also disclosed.

It is to be understood that the above description is intended to be illustrative, and not restrictive. Other implementations will be apparent to those of skill in the art upon reading and understanding the above description. The scope of the disclosure may, therefore, be determined with reference to the appended claims, along with the full scope of equivalents to which such claims are entitled.

What is claimed is:

1. A device, comprising:
a receiver coupled with a link and comprising control logic, the control logic configured to:
receive data bits corresponding to a first set of data;
perform, based on receiving the data bits, a forward error correction (FEC) operation on the data bits to generate an error location and perform a cyclic redundancy check (CRC) operation on the data bits to generate a first CRC value, wherein the CRC operation and the FEC operation are performed concurrently;
determine, after performing the FEC operation, a second CRC value based on the error location; and
generate, based on the second CRC value, a third CRC value corresponding to the first set of data after determining the second CRC value.

2. The device of claim 1, wherein to generate the third CRC value, the control logic configured to:
perform an exclusive OR (XOR) operation with the first CRC value and the second CRC value.

3. The device of claim 1, wherein the second CRC value is determined at a CRC component, the CRC component comprising a table storing a plurality of CRC values, and wherein the plurality of CRC values comprises the second CRC value.

4. The device of claim 3, wherein to determine the second CRC value, the CRC component configured to:
receive the error location;
compare the error location with the table storing the plurality of CRC values based on receiving the error location; and
determine the second CRC value corresponds to the error location received based on comparing the error location with the table.

5. The device of claim 1, wherein the data bits corresponding to the first set of data includes CRC values and FEC code.

6. The device of claim 1, wherein the link is a peripheral component interconnect express (PCIe).

7. The device of claim 1, wherein the control logic is configured to:
determine an absence of errors responsive to performing the FEC operation; and
refrain from generating the second CRC value based on determining the absence of errors.

8. A method comprising:
receiving, at a receiver of a device, data bits corresponding to a first set of data; performing, based on receiving the data bits, a forward error correction (FEC) operation on the data bits to generate an error location and performing a cyclic redundancy check (CRC) operation on the data bits to generate a first CRC value, wherein the CRC operation and the FEC operation are performed concurrently;
determining, after performing the FEC operation, a second CRC value based on the error location; and
generating, based on the second CRC value, a third CRC value corresponding to the first set of data after performing the CRC operation and determining the second CRC value.

9. The method of claim 8, further comprising:
performing an exclusive OR (XOR) operation with the first CRC value and the second CRC value, wherein generating the third CRC is based at least in part on performing the XOR operation.

10. The method of claim 8, wherein the second CRC value is determined at a CRC component comprising a table storing a plurality of CRC values, the plurality of CRC values comprising the second CRC value.

11. The method of claim 10, further comprising:
receiving the error location at the CRC component;
comparing the error location with the table storing the plurality of CRC values based on receiving the error location; and
determining the second CRC value corresponds to the error location received based on comparing the error location with the table.

12. The method of claim 8, wherein the data bits corresponding to the first set of data includes CRC values and FEC code.

13. The method of claim 8, wherein the receiver is coupled with a link, and wherein the link is a peripheral component interconnect express (PCIe).

14. The method of claim 8, further comprising:
determining an absence of errors responsive to performing the FEC operation; and
refraining from generating the second CRC value based on determining the absence of error.

15. A receiver comprising:
a first cyclic redundancy check (CRC) component to perform a first CRC operation and generate a first CRC value on data bits received;
a forward error correction (FEC) component to perform an FEC operation and determine an error location associated with the data bits received, wherein the first CRC operation and the FEC operation are performed concurrently;
a second CRC component coupled to the FEC component and to perform a second CRC operation and generate a second CRC value based on the error location determined; and
an exclusive OR (XOR) logic to logically combine the first CRC value and the second CRC value and generate a third CRC value associated with the data bits received.

16. The receiver of claim 15, wherein the second CRC component further comprises a table storing a plurality of CRC values, and wherein the plurality of CRC values comprises the second CRC value.

17. The receiver of claim 16, wherein the second CRC component is to:
receive the error location;
compare the error location with the table storing the plurality of CRC values based on receiving the error location; and
determine the second CRC value corresponds to the error location received based on comparing the error location with the table.

18. The receiver of claim 15, wherein the data bits received correspond to a first set of data comprising CRC values and FEC code.

19. The receiver of claim 15, wherein:
the FEC component is to determine an absence of errors responsive to performing the FEC operation; and
the second CRC component is to refrain from generating the second CRC value based on the FEC component determining the absence of errors.

20. The receiver of claim 15, wherein the receiver is coupled with a link, and wherein the link is a peripheral component interconnect express (PCIe).
